(19) United States
(12) Patent Application Publication
(10) Pub. No.: US 2015/0179825 A1
(43) Pub. Date: Jun. 25, 2015

(54) DIODE DEVICE AND METHOD OF MANUFACTURING THE SAME

(71) Applicant: SAMSUNG ELECTRO-MECHANICS CO., LTD., Suwon (KR)

(72) Inventors: Jae Kyu SUNG, Suwon (KR); Chang Su Jang, Suwon (KR); In-Hyuk Song, Suwon (KR); Kyu Hyun Mo, Suwon (KR); Sun Jae Yoon, Suwon (KR)

(73) Assignee: SAMSUNG ELECTRO-MECHANICS CO., LTD., Suwon (KR)

(21) Appl. No.: 14/332,958

(22) Filed: Jul. 16, 2014

(30) Foreign Application Priority Data
Dec. 23, 2013 (KR) 10-2013-0161511

(51) Int. Cl. H01L 29/861; H01L 21/265; H01L 29/06; H01L 29/66; H01L 29/36

(52) U.S. Cl. CPC H01L 29/8613; H01L 29/66136; H01L 29/36; H01L 29/06; H01L 21/265

(57) ABSTRACT

A diode device may include a first conductivity type first semiconductor region, a second conductivity type second semiconductor region partially formed inside an upper portion of the first semiconductor region, and second conductivity type third semiconductor regions partially formed inside the upper portion of the first semiconductor region, formed on sides of the second semiconductor region, and having an impurity concentration higher than that of the second semiconductor region.

### CROSS-REFERENCE TO RELATED APPLICATION

This application claims the benefit of Korean Patent Application No. 10-2013-0161511 filed on Dec. 23, 2013, with the Korean Intellectual Property Office, the disclosure of which is incorporated herein by reference.

### BACKGROUND

The present disclosure relates to a diode device and a method of manufacturing the same.

A diode is a semiconductor device having effects such as luminescence, as well as rectification properties.

Such a diode is configured by a p-n junction formed by a junction between a p-type semiconductor and an n-type semiconductor.

When the p-n junction is formed by the junction between the p-type semiconductor and the n-type semiconductor, electrons present in the n-type semiconductor are diffused into a p-type semiconductor region in which a number of holes are present.

The diffused electrons are combined with the holes present within the p-type semiconductor region and the p-n junction portion is formed with a depletion region in which carriers are no longer present.

When the p-type semiconductor region has a positive (+) voltage applied thereto and the n-type semiconductor region has a negative (−) voltage applied thereto, the depletion region disappears and thus a current flows through the diode.

On the other hand, when the p-type semiconductor region and the n-type semiconductor region have reverse-bias such as a negative (−) voltage being applied to the p-type semiconductor region and a positive (+) voltage being applied to the n-type semiconductor region, the depletion region is further extended and carriers are not present in the depletion region, and therefore a current does not flow through the diode.

That is, in the reverse-bias area, an extremely small amount of current passes through the diode.

However, when a voltage exceeds a reverse critical voltage or a withstanding voltage level, the diode causes avalanche breakdown and thus, a large current may flow in reverse, such that the diode device may be destructed.

The reverse critical voltage may be improved by lowering a diode concentration in the n-type semiconductor region and increasing a thickness of the n-type semiconductor region.

However, as the thickness of the n-type semiconductor region is increased, a forward voltage drop is increased.

That is, a method of increasing the reverse critical voltage while lowering the forward voltage drop is required.

Recently, a fast switching diode requires soft recovery characteristics as well as fast switching characteristics.

Among diodes, a generally used p-n junction diode uses minority carriers, and therefore a forward voltage may be lowered by a conductivity modulation effect.

However, the fast switching diode may have reverse recovery characteristics due to the minority carrier and thus fast switching characteristics may be deteriorated.

The reverse recovery characteristics allow a large reverse current to instantly flow in the p-n junction diode when the p-n junction diode is suddenly applied with a voltage in a reverse direction in the state in which a forward current flows in the p-n junction diode. The reason is that the implanted minority carriers move in reverse in the p-n junction diode, and therefore, the large reverse current may refer to a current flowing in the p-n junction diode until the minority carriers flow out or disappear.

The fast switching diode has soft recovery characteristics by shortening a period (reverse recovery time trr) until the reverse current reaches 0 and smoothing a reverse current waveform.

According to the related art, to form the p-n junction diode, a p-type body region is formed by implanting p-type impurities into a portion of an upper portion of the n-type drift region.

After the p-type body region is formed, an n-type drift region and the p-type body region are partially covered with an insulating layer and the remaining portion of the upper portion of the p-type body region has a metal layer formed thereon, such that the p-type body region may be electrically connected to the metal layer.

However, a metal oxide semiconductor (MOS) structure may be formed due to the insulating layer interposed between the metal layer formed on the p-type body region and the p-type body region and thus a conductive channel may be formed in the corresponding portion, such that a leakage current may occur.

The following Related Art Document discloses a semiconductor diode capable of enhancing snap recovery characteristics and reducing a forward voltage by allowing a trap level concentration of a substrate, on which a fast recovery diode and a ring are formed, to be higher in a diode forming region than in a ring forming region, and the semiconductor diode includes a semiconductor substrate in which a diode device formed by a semiconductor region and a ring region formed around diode device are formed, an electrode layer connected to the semiconductor region is formed, a protective layer is formed on the structure, an open metal layer is formed on the protective layer to correspond to a diode device region to perform electron irradiation over the entire surface of the substrate, to thereby relatively increase the trap concentration of the substrate region in which the diode device is formed.

### RELATED ART DOCUMENT

Korean Patent No. 10-0345963

### SUMMARY

Some embodiments of the present disclosure may provide a power semiconductor device and a method of manufacturing the same capable of reducing a leakage current.

According to some embodiments of the present disclosure, a diode device may include: a first conductivity type first semiconductor region; a second conductivity type second semiconductor region partially formed inside an upper portion of the first semiconductor region; and second conductivity type third semiconductor regions partially formed inside the upper portion of the first semiconductor region, formed on sides of the second semiconductor region, and having an impurity concentration higher than that of the second semiconductor region.

The diode device may further include: an insulating layer formed on an upper portion of the first semiconductor region and an upper portion of the third semiconductor region.

The diode device may further include: a first metal layer formed on an upper portion of the insulating layer and on an upper portion of the second semiconductor region.

The diode device may further include: a fourth semiconductor region formed between the first semiconductor region and the second semiconductor region and having an impurity concentration higher than that of the first semiconductor region.

The diode device may further include: a second metal layer formed below the first semiconductor region.

According to some embodiments of the present disclosure, a method of manufacturing a diode device may include: preparing a first conductivity type first semiconductor region; implanting a second conductivity type impurity into an upper portion of the first semiconductor region to form a second semiconductor region thereon; and implanting a second conductivity type impurity into sides of the second semiconductor region to form a second conductivity type third semiconductor region having an impurity concentration higher than that of the second semiconductor region on the sides of the second semiconductor region.

The method of manufacturing a diode device may further include: forming an insulating layer on an upper portion of the first semiconductor region and an upper portion of the third semiconductor region.

The method of manufacturing a diode device may further include: forming a first metal layer on an upper portion of the insulating layer and an upper portion of the second semiconductor region.

The method of manufacturing a diode device may further include: after the preparing of the first semiconductor region, implanting a first conductivity type impurity into a portion of the upper portion of the first semiconductor region to form a fourth semiconductor region on the first semiconductor region.

The method of manufacturing a diode device may further include: forming a second metal layer below the first semiconductor region.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view of a diode device according to an exemplary embodiment of the present disclosure;

FIG. 2 is a schematic cross-sectional view of the diode device further including a fourth semiconductor region according to an exemplary embodiment of the present disclosure;

FIG. 3 is a flow chart illustrating a method of manufacturing a diode device according to another exemplary embodiment of the present disclosure; and

FIGS. 4 through 9 are cross-sectional views illustrating respective processes in the method of manufacturing a diode device according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

In the accompanying drawings, x, y, and z directions refer to width, length, and thickness directions, respectively.

A power switch may be implemented by a power MOSFET, an IGBT, a thyristor, and any one of devices similar thereto. Most new technologies disclosed herein will be described based on a diode. However, several exemplary embodiments of the present disclosure disclosed herein are not only applicable to diodes, but may be applied to, for example, other types of power switches including power MOSFETs and various types of thyristors in addition to diodes. In addition, several exemplary embodiments of the present disclosure are described as including a specific p-type region and n-type region. However, several exemplary embodiments of the present disclosure may also be applied to a device in opposite cases to the conductivity types of several regions disclosed herein.

Further, the n-type and the p-type used herein may be defined as a first conductivity type and a second conductivity type. Meanwhile, the first conductivity type and the second conductivity type mean different conductivity types.

Further, generally, positive ‘+’ refers to a high-concentration doped state and negative ‘−’ refers to a low-concentration doped state.

Hereinafter, for clear description, the first conductivity type will be described as an n-type and the second conductivity type will be described as a p-type. However, the present disclosure is not limited thereto.

Further, for clarity of description, a first semiconductor region will be described as a drift region and a second semiconductor region will be described as a body region. However, the present disclosure is not limited thereto.

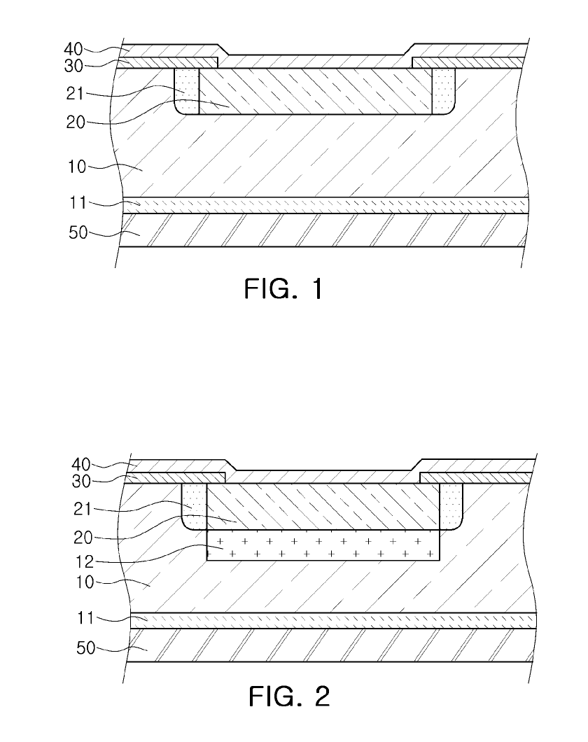

FIG. 1 illustrates a schematic cross-sectional view of a diode device according to an exemplary embodiment of the present disclosure.

A structure of the diode device according to the exemplary embodiment of the present disclosure will be described with reference to FIG. 1.

The diode device according to the exemplary embodiment of the present disclosure may include a drift region 10, a body region 20 formed inside an upper portion of the drift region 10, and third semiconductor regions 21 formed on sides of the body region 20.

The drift region 10 may be formed with low-concentration n-type impurities.

The drift region 10 may be formed to have a proper thickness by an epitaxial method.

The upper portion of the drift region 10 may be formed with a p-type body region 20.

Since the body region 20 has a p-type conductivity type, a depletion layer may be formed at a boundary at which the body region 20 contacts the drift region 10.

For example, electrons are combined with holes at the boundary where the n-type drift region 10 contacts the p-type body region 20 to then disappear.

Therefore, regions in which carriers are not present are formed on both sides based on a boundary between the drift region 10 and the body region 20 and are called the depletion layer.

When the body region 20 has a positive voltage applied thereto and the drift region 10 has a negative voltage applied thereto, the depletion layer gradually narrows and then disappears.

When a p-type semiconductor region has a positive (+) voltage applied thereto and an n-type semiconductor region has a negative (−) voltage applied thereto, a depletion region disappears, and thus a current flows through a diode.

To the contrary, when the p-type semiconductor region and the n-type semiconductor region have a reverse bias such as a negative (−) voltage being applied to the p-type semiconductor region and a positive (+) voltage being applied to the n-type semiconductor region, the depletion region is further extended and carriers are not present in the depletion region, and therefore a current does not flow through the diode.

However, when a voltage exceeds a reverse critical voltage or a withstanding voltage level, the diode causes avalanche breakdown and thus a large current may flow in reverse, such that the diode device may be destructed.

For example, in a voltage having a level equal to or less than that of the reverse critical voltage, there is a need to prevent a current from flowing in the diode device.

A current of the diode device, flowing in the voltage having a level equal to or less than that of the reverse critical voltage, is known as a leakage current.

An upper surface of the body region 20 may be formed with a first metal layer 40 so as to contact the body region 20.

The first metal layer 40 should not contact the drift region 10.

In a case in which the first metal layer 40 contacts the drift region 10, a current may flow in the diode device independently of a voltage application direction, and therefore, the diode device may not properly be operated.

Therefore, an insulating layer 30 may be formed from a portion of the upper surface of the body region 20 to an upper surface of the drift region 10 so that the first metal layer 40 may be insulated from the drift region 10.

The insulating layer 30 is formed using silicon oxide (SiO₂).

The p-type body region 20 is generally formed on the drift region 10 by implanting boron in the upper surface of the drift region 10 and when the insulating layer 30 is formed using the silicon oxide (SiO₂), boron segregation occurs at an interface at which the body region 20 contacts the insulating layer 30.

When the boron segregation occurs, a p-type impurity concentration of the corresponding portion is reduced.

Since the depletion layer formed by a contact between the drift region 10 and the body region 20 is weakened, a current flows through the portion at which the p-type impurity concentration is reduced.

For example, when the diode device has a reverse voltage applied thereto, a current need not flow in the diode device, but the leakage current may flow in the diode device due to the boron segregation.

Therefore, the diode device according to the exemplary embodiment of the present disclosure may include third semiconductor regions 21 formed on sides of the body region 20.

The third semiconductor region 21 includes high-concentration p-type impurities and has an impurity concentration higher than that of the body region 20.

Therefore, when the insulating layer 30 contacts the third semiconductor region 21, the depletion layer is not weakened at a corresponding portion even when the boron segregation occurs.

Therefore, the diode device according to the exemplary embodiment of the present disclosure may significantly reduce the leakage current.

A lower portion of the drift region 10 may be formed with a buffer region 11.

The buffer region 11 may be formed on the drift region 10 through implantation of higher-concentration impurities thereof than the drift region 10.

Since the buffer region 11 is formed using the high-concentration n-type impurities, the buffer region 11 may serve to stop an extension of the depletion layer when a reverse voltage is applied to the diode device.

Therefore, the buffer region 11 may help to allow the thickness of the drift region 10 to be thin.

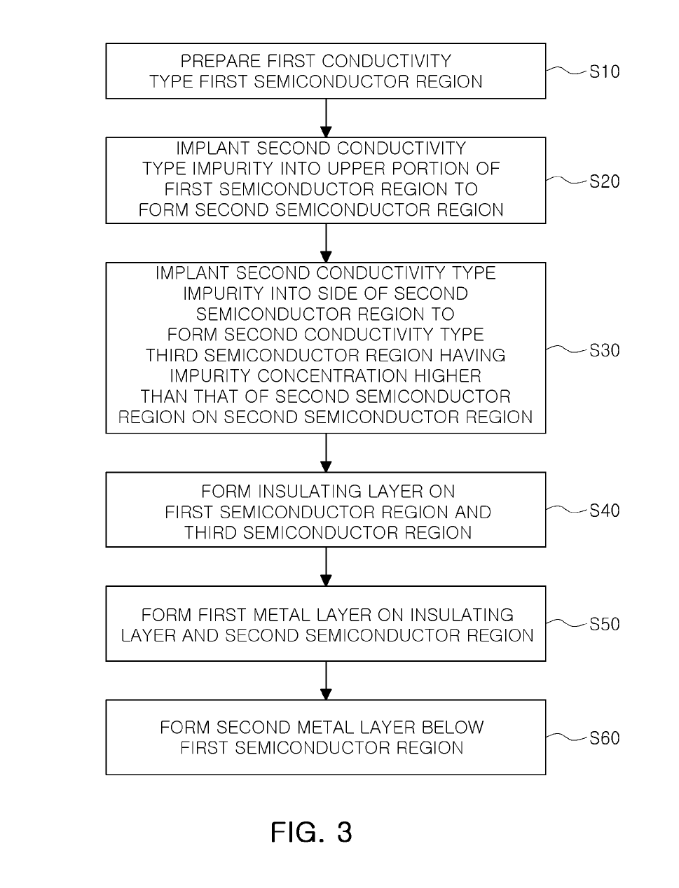

FIG. 2 illustrates a schematic cross-sectional view of the diode device further including a fourth semiconductor region 12 formed below the body region 20.

Referring to FIG. 2, the diode device may further include the fourth semiconductor region 12 formed beneath the body region 20 by implanting high-concentration n-type impurities into the lower portion of the body region 20.

When the diode device is turned off, the fourth semiconductor region 12 may provide a recombination center in which the carriers may disappear.

For example, the fourth semiconductor region 12 provides the recombination center, and thus a reverse recovery time may be reduced and soft recovery characteristics may be implemented.

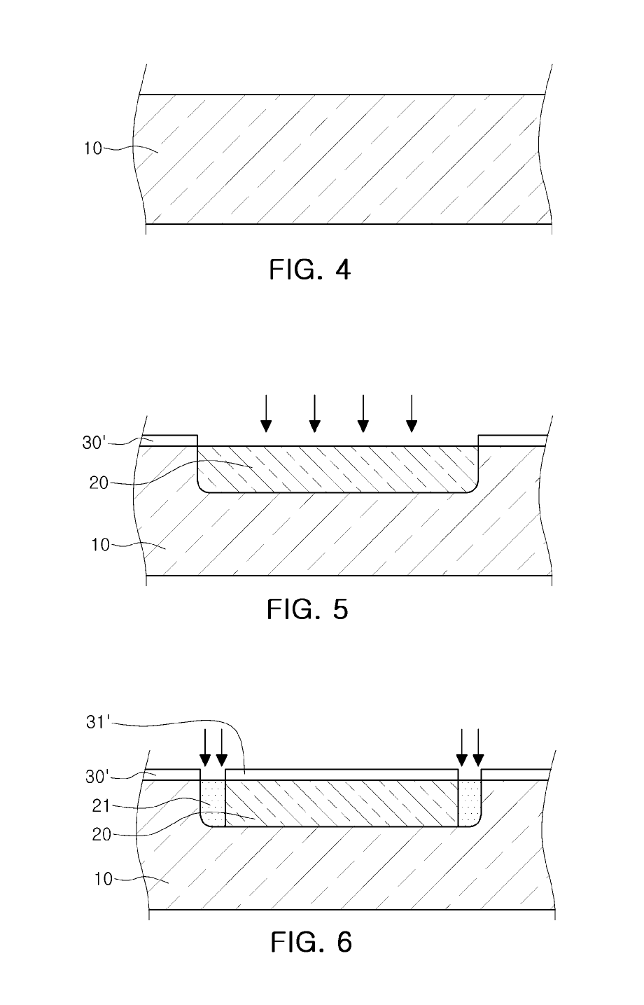

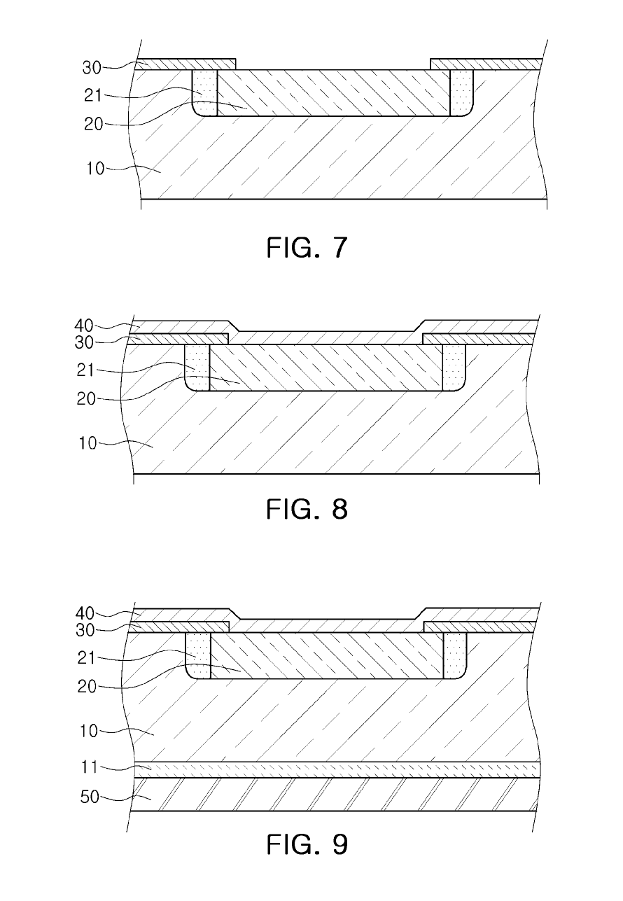

FIG. 3 illustrates a method of manufacturing a diode device according to another exemplary embodiment of the present disclosure and FIGS. 4 through 9 are cross-sectional views of respective manufacturing processes.

The method of manufacturing a diode device according to another exemplary embodiment of the present disclosure will be described with reference to FIG. 3 and figures of the corresponding process.

Referring to FIG. 4, preparing a first conductivity type drift region 10 (S10) may be performed.

The drift region 10 may be formed by an epitaxial method.

The drift region 10 may be formed by depositing a semiconductor region having low-concentration n-type impurities on a substrate including high-concentration n-type impurities.

When the substrate including the high-concentration n-type impurities is used, the substrate may serve as the buffer region without a separate process.

Next, as illustrated in FIG. 5, implanting the p-type impurities into the upper portion of the drift region 10 to form the body region 20 on the drift region 10 (S20) may be performed.

The body region 20 may be formed by forming a first mask layer 30′ on the upper surface of the drift region 10 and implanting the p-type impurities into the upper portion of the drift region 10.

For example, the body region 20 may be formed on the drift region 10 by implanting boron into the upper portion of the drift region 10.

The body region 20 may be formed on the drift region 10 by implanting relatively low-concentration impurities into the upper portion of the drift region 10 so as to enhance the recovery characteristics of the diode device.

Next, as illustrated in FIG. 6, implanting the p-type impurities into the sides of the body region 20 to form the third semiconductor regions on the sides of the body region 20 (S30) may be performed.

A second mask layer 31′ may be formed to open the sides of the body region 20.

The second mask layer 31′ is formed and the p-type impurities may be further implanted into the opening portion.

The third semiconductor regions 21 may be formed on the sides of the body region 20 by further implanting the p-type impurities into the sides of the body region 20.

When the forming of the body region 20 (S20) is performed, to enhance the recovery characteristics of the diode device, in the completed diode device in the case in which the body region 20 is formed on the drift region 10 by implanting the low-concentration impurities into the upper portion of the drift region 10, the metal layer, the insulating layer, and a metal oxide semiconductor (MOS) structure of the body region are formed and thus a conductive channel may be formed.

However, the diode device formed by the method of manufacturing a diode device according to the exemplary embodiment of the present disclosure may prevent the conductive channels from being formed by implanting the high-concentration p-type impurities into the sides of the body region 20.

Next, as illustrated in FIG. 7, forming the insulating layer 30 on the drift region 10 and the third semiconductor region 21 (S40) may be performed.

The forming of the third semiconductor region (S30) is performed, and the mask layers 30′ and 31′ are removed and then the insulating layer 30 may be formed on the drift region 10 and the third semiconductor region 21.

The insulating layer 30 may be formed by depositing the silicon oxide and may also be formed by depositing and oxidizing amorphous silicon.

After the forming of the insulating layer 30 (S40), as illustrated in FIG. 8, forming the first metal layer 40 on the insulating layer 30 and the body region 20 (S50) may be performed.

In the forming of the first metal layer 40 (S50), the body region 20 may be electrically connected to the first metal layer 40.

The first metal layer 40 may be formed using metals having excellent conductivity such as Al, Au, and Ag or an alloy thereof, but is not limited thereto.

Finally, as illustrated in FIG. 9, forming a second metal layer 50 on a lower surface of the drift region 10 (S60) may be performed.

In the forming of the second metal layer 50 (S60), the drift region 10 may be electrically connected to the second metal layer 50.

The second metal layer 50 may be formed using metals having excellent conductivity such as Al, Au, and Ag or an alloy thereof, but is not limited thereto.

Prior to the forming of the second metal layer 50 (S60), the thickness of the drift region 10 may be controlled by partially removing the lower surface of the drift region 10.

When the lower surface of the drift region 10 is partially removed, the buffer layer 11 may also be formed beneath the drift region 10 by implanting the high-concentration n-type impurities into the lower surface of the drift region 10.

Further, the method of manufacturing a diode device according to the exemplary embodiment of the present disclosure may further include implanting the first conductivity type impurities into the upper portion of the drift region 10 to form the fourth semiconductor region 12 on the drift region 10 after the preparing of the drift region (S10) is performed.

The fourth semiconductor region 12 may also be formed by irradiating an electron beam or implanting the n-type impurities having high energy and then performing heat treatment.

As set forth above, according to the exemplary embodiment of the present disclosure, the diode device has the p+-type third semiconductor regions formed on the sides of the p-type body region, to thereby reduce the leakage current which may occur in the diode device.

While exemplary embodiments have been shown and described above, it will be apparent to those skilled in the art that modifications and variations could be made without departing from the spirit and scope of the present disclosure as defined by the appended claims.

What is claimed is:

1. A diode device, comprising:
a first conductivity type first semiconductor region;
a second conductivity type second semiconductor region partially disposed inside of an upper portion of the first semiconductor region; and
second conductivity type third semiconductor regions partially disposed inside of the upper portion of the first semiconductor region, disposed on sides of the second semiconductor region, and having an impurity concentration higher than that of the second semiconductor region.

2. The diode device of claim 1, further comprising an insulating layer formed on an upper portion of the first semiconductor region and on an upper portion of the third semiconductor region.

3. The diode device of claim 2, further comprising a first metal layer formed on an upper portion of the insulating layer and on an upper portion of the second semiconductor region.

4. The diode device of claim 1, further comprising a fourth semiconductor region formed between the first semiconductor region and the second semiconductor region and having an impurity concentration higher than that of the first semiconductor region.

5. The diode device of claim 1, further comprising a second metal layer formed below the first semiconductor region.

6. A method of manufacturing a diode device, comprising:
preparing a first conductivity type first semiconductor region;
implanting a second conductivity type impurity into an upper portion of the first semiconductor region to form a second semiconductor region on the first semiconductor region; and
implanting a second conductivity type impurity into sides of the second semiconductor region to form second conductivity type third semiconductor regions having an impurity concentration higher than that of the second semiconductor region on the sides of the second semiconductor region.

7. The method of claim 6, further comprising forming an insulating layer on an upper portion of the first semiconductor region and an upper portion of the third semiconductor region.

8. The method of claim 7, further comprising forming a first metal layer on an upper portion of the insulating layer and an upper portion of the second semiconductor region.

9. The method of claim 6, further comprising, after the preparing of the first semiconductor region, implanting a first conductivity type impurity into a portion of the upper portion of the first semiconductor region to form a fourth semiconductor region on the first semiconductor region.

10. The method of claim 6, further comprising forming a second metal layer below the first semiconductor region.
